(19) United States
(12) Patent Application Publication
(10) Pub. No.: US 2003/0115519 A1
(43) Pub. Date: Jun. 19, 2003

(54) Parallel testing system for semiconductor memory devices

(75) Inventors: Hyuk Kwon, Chungcheongnam-do (KR); Jeong-Ho Bang, Kyungki-do (KR); Hyun-Seop Shim, Kyungki-do (KR); Yong-Woon Kim, Chungcheongnam-do (KR); Hyoung-Young Lee, Kyungki-do (KR); Young-Gu Shin, Chungcheongnam-do (KR)

Correspondence Address: MARGER JOHNSON & McCOLLOM, P.C., 1030 S.W. Morrison Street, Portland, OR, 97205, US

(73) Assignee: Samsung Electronics Co., Ltd.

(21) Appl. No.: 10/227,062

(22) Filed: Aug. 22, 2002

(30) Foreign Application Priority Data
Dec. 19, 2001 (KR) 2001-81161

(51) Int. Cl. G11C 29/00

(52) U.S. Cl. 714/718

(57) ABSTRACT

A testing system for memory Devices Under Test (DUTs) uses an improved wiring scheme to increase the parallel test number. In a preferred embodiment, the parallel testing system increases the parallel test number by commonly connecting data input/output pins of the memory devices to an input/output channel of the testing system. Driving channels may also be connected in parallel to driving pins of the plurality of semiconductor memory devices under test.

### BACKGROUND OF THE INVENTION

This application claims priority from Korean Patent Application No. 2001-81161, filed Dec. 19, 2001 the contents of which are incorporated herein by reference in their entirety.

1. Field of the Invention

The present invention relates generally to a testing system for semiconductor memory devices, and more particularly, to a parallel testing system that can increase the number of parallel tests performed on a semiconductor memory Device Under Test (DUT).

2. Description of the Related Art

In general, testing a semiconductor memory device includes testing direct current (DC), alternating current (AC), and functional characteristics of the DUT using a memory tester. A conventional memory tester generally comprises a computer, a DC measuring unit, a test pattern generator, and a timing generator. The computer controls the entire testing system and measures data according to a test program. The DC measuring unit measures the application of source voltage when the semiconductor memory device characteristics are tested. The test pattern generator generates an address and data under the control of the computer and changes the data and the form and order of the address according to a specific test program algorithm to provide a measuring signal wave pattern. The timing generator generates the measuring signal wave pattern along with the test pattern generator.

A DC test is used to measure current while applying a specific voltage to each pin of the semiconductor memory device. The DC test can also be used to measure voltage while applying a specific current. The DC test determines the stability of power lines, the amount of current consumption, and the amount of current leakage in a memory chip.

An AC test measures the rising and falling time of an output signal while providing a pulse signal to the input terminal of the memory chip. The pulse signal is provided by alternating a logic “high” and a logic “low” level. The AC test further measures dynamic characteristics such as a level input/output transmission delay time and an access time.

A function test compares an output of the memory chip with an expected pattern after providing the memory chip with a specific test pattern from the test pattern generator. The function test also confirms normal operation of a region while varying the input voltage of the memory chip. The function test further evaluates the various test patterns while varying test conditions such as an input voltage, an input level, and clock signal timing. The test pattern comprises an address sequence for selecting a memory cell, a stored data of the memory cell, and various clock signals.

In general, a parallel test is used to save time when manufacturing memory devices. During parallel testing, two or more memory chips are simultaneously tested while commonly applying driving signals, data, and power voltage. FIG. 1 shows a conventional parallel testing system 10. Referring to FIG. 1, signal lines respectively connect data input/output pins DQi, DQj and driving pins DRi, DRj of first and second memory devices under test DUT1 12 and DUT2 14 to input/output channels Pij, Pji and driving channels Dpij, Dpji in a one-to-one correspondence. Accordingly, if the total number of data input-out pins DQi, DQj is sixteen, for example, sixteen input/output channels Pij, Pji are needed.

Accordingly, the number of memory devices 12, 14 that the conventional parallel testing system 10 can test at once (called the “parallel test number”) is limited by the number of input/output channels Pij, Pji. More particularly, the parallel test number is determined by dividing the number of the input/output channels Pij, Pji with the number of the data input/output pins DQi, DQj of one memory device.

### SUMMARY OF THE INVENTION

One object of the present invention is to increase the number of semiconductor memory devices that can be tested in parallel (i.e., to increase the parallel test number) using a limited number of input/output channels in a test system.

Another object of the present invention is to permit simultaneous testing of memory devices of the same size having different pin counts (e.g., x4, x8, or x16).

A parallel testing system for semiconductor memory devices increases the parallel test number using improved connections between data input/output pins of memory devices to be tested and input/output channels of a test board. Improved connections can be obtained, for example, by merging corresponding pins or by interposing a switch between the pin and the channel.

According to one aspect of the present invention, a parallel testing system includes a test board and a plurality of switches. The test board preferably has data input/output channels to which respective input/output pins of the memory devices are connected in parallel. The switches selectively connect the data input/output pins of the semiconductor memory devices to the input/output channels of the test board. Testing of the memory devices can be performed either sequentially or simultaneously depending on the switch selection of the data input/output pins of the semiconductor memory device. In the parallel testing system of this embodiment, the test board may further include driving channels, to which driving pins of the semiconductor memory devices are connected in parallel.

According to another aspect of the present invention, a parallel testing system can include a test board and a clock. The test board can again have data input/output channels to which data input/output pins of semiconductor memory devices are connected in parallel. The clock sequentially selects one of the semiconductor memory devices. The selected device produces an output signal in accordance with a test signal of the tester. The output signal of the semiconductor memory device selected by the clock is output through the input/output channel while the output signals of the other semiconductor memory devices are kept at high impedance. Testing of the semiconductor memory devices in this embodiment is therefore preferably performed sequentially based on sequential selection by the clock.

### BRIEF DESCRIPTION OF THE DRAWINGS

The foregoing benefits and advantages, along with other features and advantages of the present invention, will be more clearly understood through the following detailed description of preferred embodiments, made with reference to the accompanying figures. These figures are not necessarily drawn to scale. In the accompanying figures:

FIG. 1 is a block diagram of a conventional parallel testing system for semiconductor memory devices.

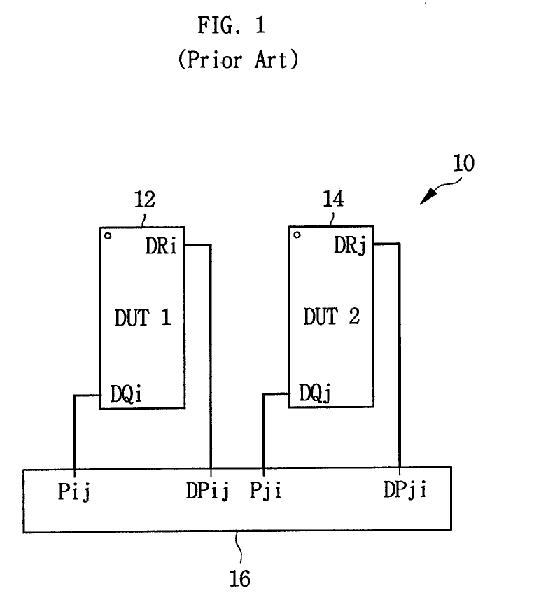

FIG. 2 is a block diagram illustrating a parallel testing system for semiconductor memory devices according to an embodiment of the present invention.

FIG. 3 is a schematic circuit and timing diagram of the parallel testing system of FIG. 2.

FIG. 4 is a block diagram illustrating a parallel testing system for semiconductor memory devices according to another embodiment of the present invention.

FIG. 5 is a schematic circuit diagram of the parallel testing system of FIG. 4.

### DETAILED DESCRIPTION OF PREFERRED EMBODIMENTS

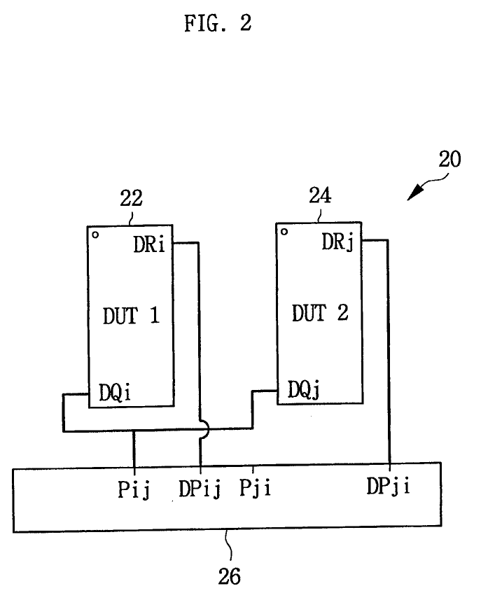

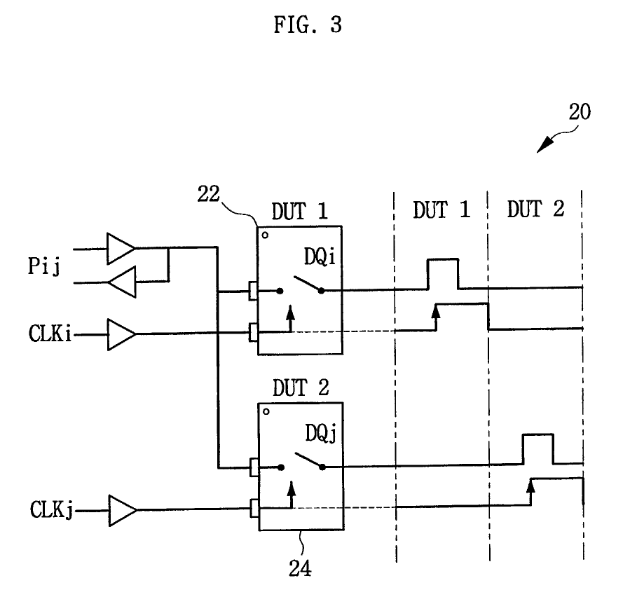

FIG. 2 is a block diagram of a parallel testing system 20 for testing semiconductor memory devices 22, 24 according to one embodiment of the present invention. FIG. 3 is schematic circuit and timing diagram of the parallel testing system 20 shown in FIG. 2. Referring to FIGS. 2 and 3, the parallel testing system 20 of this embodiment includes a tester having a test board 26. The test board 26 supplies data input/output signals and driving signals to data input/output pins DQi, DQj and driving pins DRi, DRj, respectively, of the memory devices under test 22, 24. The parallel testing system 20 also includes power voltage channels (not shown) that correspond to power voltage pins (not shown) of the semiconductor memory devices 22, 24, as well as clock channels CLKi, CLKj corresponding to various clock signal pins.

To increase the parallel test number, corresponding data input/output pins DQi, DQj of the memory devices 22, 24 in the parallel testing system 20 are merged (i.e., commonly connected) to a single input/output channel Pij of the test board 26. Because multiple pins are thereby connected to a single channel, the parallel test number can be increased. Although this embodiment uses two devices 22, 24 for clarity and ease of explanation, more than two memory devices could also be used.

It is possible to simultaneously provide a test signal to both of the semiconductor memory devices 22, 24 through the input/output channel Pij. Because of collisions between output signals, however, output signals of the two semiconductor memory devices 22, 24 are not simultaneously extracted through the input/output channel Pij. The output signals of the input/output pins DQi, DQj are therefore preferably separated.

Referring to FIG. 3, according to one of many feasible circuit implementations of the foregoing embodiment, when two semiconductor memory devices 22, 24 are input/output tested, the output signal of the second memory device 24 is kept at high impedance (Hi-Z or tri-status logic). When the second semiconductor device 24 is input/output-tested, the output signal of the first semiconductor 22 is kept at high impedance. In this manner, sequential tests are possible. A sequence for reading the output signals can be determined by a specific clock signal CLKi, CLKj provided to the first and second memory devices 22, 24.

The embodiment described previously uses a common connection between the data input/output pins and a single input/output channel. According to an alternate embodiment, a common connection between the driving pins and a single driving channel can be provided. In yet another embodiment, a switch can be used instead of a direct connection between the data input/output pin and the channel.

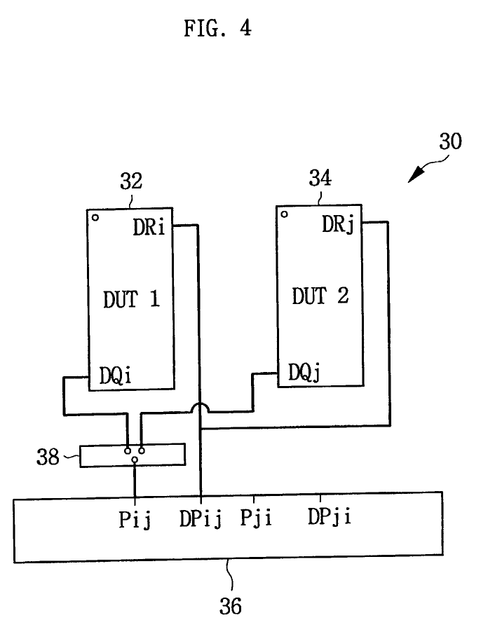

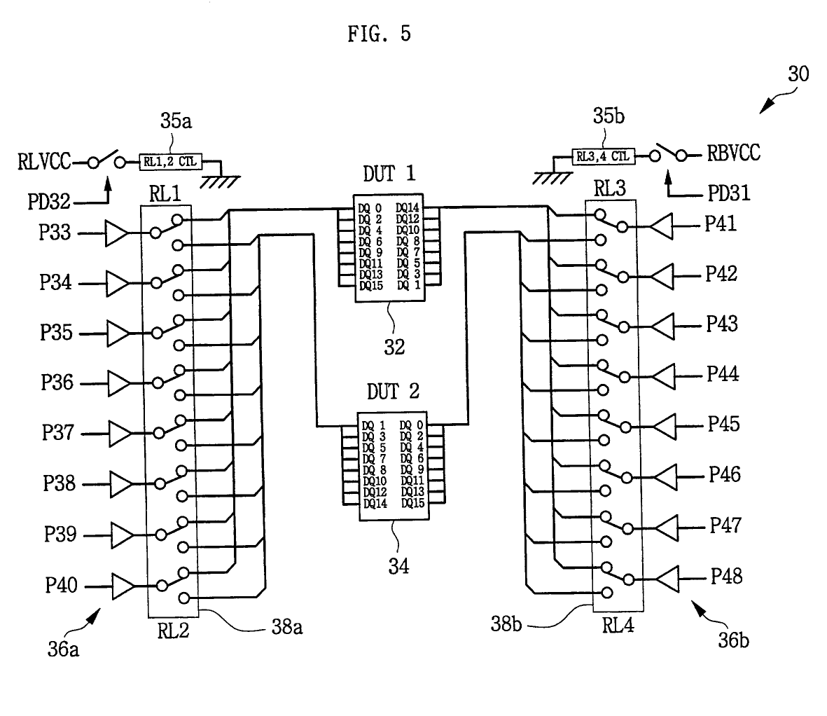

FIGS. 4 and 5 illustrate another embodiment of the present invention. Referring to FIGS. 4 and 5, a parallel testing system 30 for testing semiconductor memory devices includes a tester having a test board 36. The test board 36 respectively supplies data input/output signals and driving signals to the data input/output pins DQi, DQj and driving pins DRi, DRj of the memory devices 32, 34. The system 30 also includes a power voltage channel (not shown) that corresponds to a power voltage pin (not shown) of the semiconductor memory devices 32, 34, as well as a clock channel (not shown) corresponding to a clock signal pin.

The parallel testing system 30 of this embodiment uses two common connections to increase the parallel test number. A first common connection is made between the input/output channel Pij and the data input/output pins DQi, DQj. A second common connection is made between the driving channel DPij and the driving pins DRi, DRj. More specifically, the data input/output pins DQi, DQj are commonly connected to the input/output channel Pij through a switch. The driving pins DRi, DRj, on the other hand, are directly connected in common to the driving channel DPij. The switch permits connection of the input/output channel Pij to a selected one of the memory devices 32, 34 for the input/output of test signals. Sequential testing of the memory devices is therefore possible. A simultaneous test is also possible.

Since fewer channels are used for the same number of connections, the freed channels can be used to provide additional connections and thereby generate an increased parallel test number. Although the foregoing embodiment has been described with respect to two memory devices 32, 34 for clarity and simplicity of explanation, this embodiment can also, however, use a multiple switching member to switch between more than two memory devices.

FIG. 5 is a schematic circuit diagram illustrating one of many possible circuit configurations for the testing system of FIG. 4. Referring to FIG. 5, a parallel testing system 30 capable of performing a simultaneous test. The parallel testing system 30 is configured to test memory devices having an x16 pin configuration. Among the x16 data pins, a left x8 data pins of each chip are connected to a left input/output channel via a left switch 38a. Similarly, a right x8 data pins of each chip are connected to a right input/output channel by a right switch 38b. The operation of the left and right switches 38a, 38b is controlled by a switching control signal of switching controllers 35a, 35b. A selected test can be performed through the switches 38a, 38b under the control of the switching control signal. In other words, the switches 38a, 38b are preferably operated through the switching control signal to connect the data input/output pins of the semiconductor memory device with left and right input/output channels 36a, 36b. Although the input/output channels 36a, 36b are shown separately in FIG. 5, the left and right input/output channels 36a, 36b are preferably formed together on one test board.

The parallel testing system 30 enables testing of memory devices having the same size but different pin counts (e.g., x4, x8, or x16) using the same test board. The pin count can therefore be varied as desired for a particular application without requiring additional specialized testing equipment.

When testing a x16 pin semiconductor memory device, for example, if a first memory device 32 is tested before a second memory device 34, the left switch 38a is controlled to connect the input/output channels of the left x8 pins with the left x8 pins of the first memory device 32. The right switch 38b is controlled to connect the input/output channels of the right x8 pins with the right x8 pins of the first memory device 32. The left and right switches 38a, 38b are thereafter controlled to connect the input/output pin of the second memory device 34 with the left and right input/output channels 36a, 36b.

According to this embodiment, testing x4 or x8 pin memory devices can be accomplished using the same parallel testing system. In an input/output reduction mode test article and a DC article, the parallel test number can be increased. Namely, in devices having reduced pin counts (for example, reduced from x16 pins to x4 or x8 pins), the first memory device 32 and the second memory device 34 are selected using the left and right switches 38a, 38b and tested simultaneously. More specifically, the left switch 38a connects the left input/output channel 36a to the left data input-out pin of the first semiconductor device 32. The right switch 38b connects the right input/output channel 36b to the right data input/output pin of the first memory device 32. It is therefore possible to test the same size memory devices with different pin counts (e.g., x4, x8, or x16 pins) on the same test board. It should be noted that the switches 38a, 38b can be interchanged.

Although specific terms have been used to describe the various preferred embodiments of the invention disclosed herein, those terms have been used for explanatory purposes only and not for purposes of limitation. Various modifications to the embodiments disclosed herein will be readily apparent to those skilled in the art. The scope of this invention, as set forth in the following claims, should therefore be interpreted to cover all such variations and modifications.

For example, although the driving pins and the driving channels are not connected in parallel in certain embodiments of the present invention, it is also possible in those embodiments to connect the shorted data input/output pin to the input/output channel and to connect the shorted driving pin to the driving channel.

What is claimed is:

1. A parallel testing system for testing a plurality of semiconductor memory devices having a plurality of data input/output pins, said system comprising:
a test board comprising a data input/output channel; and
said input/output channel being connected in parallel to data input/output pins of a plurality of semiconductor memory devices under test.

2. A parallel testing system according to claim 1, wherein the test board further comprises driving channels connected in parallel to driving pins of the plurality of semiconductor memory devices under test.

3. A parallel testing system according to claim 1, further comprising a switch configured to selectively connect the data input/output pins of the semiconductor memory devices under test to the input/output channel of the test board.

4. A parallel testing system according to claim 3, wherein the switch is controlled to sequentially test the plurality of semiconductor memory devices under test.

5. A parallel testing system according to claim 3, wherein the switch is controlled to simultaneously test the plurality of semiconductor memory devices under test.

6. A parallel testing system according to claim 1, further comprising a clock configured to sequentially select the semiconductor memory devices under test.

7. A parallel testing system according to claim 6, wherein the selected device under test is configured to produce an output signal based on a test signal of the testing system.

8. A parallel testing system according to claim 7, wherein the output signal of the semiconductor memory device selected by the clock is output through the input/output channel while the output signals of the other semiconductor memory devices under test are kept at high impedance, and wherein testing for the semiconductor memory devices under test is performed sequentially based on sequential selection by the clock.

9. A parallel testing system according to claim 1, wherein the parallel testing system is configured to test semiconductor memory chips of the same size having different pin counts.

10. A parallel testing system for testing semiconductor memory devices having a plurality of data input/output pins, said testing system comprising:
a test board having a plurality of data input/output channels connected in parallel to data input/output pins of a plurality of semiconductor memory devices under test; and
a clock configured to select the semiconductor memory devices under test, wherein a selected one of the devices under test produces an output signal based on a test signal of the testing system.

11. A parallel testing system according to claim 10, wherein the output signal of the selected memory device under test is output through the input/output channel while the output signals of the other semiconductor memory devices under test are kept at a high impedance.

12. A semiconductor testing system according to claim 10, further comprising a switch configured to selectively connect the data input/output pins of the semiconductor memory devices under test to the input/output channel of the test board.

13. A semiconductor testing system according to claim 12, wherein the switch is controlled by the clock to sequentially test the plurality of semiconductor memory devices.

14. A semiconductor testing system according to claim 10, wherein the test board further comprises driving channels connected in parallel to driving pins of the plurality of semiconductor memory devices under test.

15. A method for testing semiconductor memory devices, said method comprising:
commonly connecting a plurality of input/output pins of the semiconductor memory device to an input/output channel of a testing system.

16. A method of claim 15, further comprising connecting the plurality of input/output pins to the input/output channel through a switch.

17. The method of claim 16, further comprising controlling the switch to test a plurality of semiconductor memory devices in parallel.

18. The method of claim 16, further comprising controlling the switch to sequentially test a plurality of semiconductor memory devices.

19. A method according to claim 15, further comprising directly connecting the plurality of input/output pins to the input/output channel of the testing system.

20. A method according to claim 15, further comprising testing a plurality of semiconductor devices having different pin counts using the same testing system.
